(19) United States
(12) Patent Application Publication
(10) Pub. No.: US 2010/0306579 A1
(43) Pub. Date: Dec. 2, 2010

(54) NONVOLATILE MEMORY DEVICE AND METHOD OF PROGRAMMING THE SAME

(76) Inventors: Kwang Ho Baek, Gyeonggi-do (KR); Jun Seop Chung, Gyeonggi-do (KR); Se Chun Park, Seoul (KR)

Correspondence Address: IP & T GROUP LLP, 7700 Little River Turnpike, Suite 207, Annandale, VA, 22003, US

(21) Appl. No.: 12/700,507

(22) Filed: Feb. 4, 2010

(30) Foreign Application Priority Data
May 29, 2009 (KR) 10-2009-0047819

(51) Int. Cl. G06F 11/00; G06F 12/00; G06F 12/02; G11C 11/34; G06F 11/16

(52) U.S. Cl. 714/6; 711/103; 365/185.25; 711/E12.001; 711/E12.008; 714/E11.054

(57) ABSTRACT

A nonvolatile memory device and its programming method includes a memory block having a number of memory cells, a page buffer unit coupled to the memory block and configured to temporarily store program data, to transmit the program data to the memory block, to perform a program operation for the program data, and to output the stored program in response to the memory block being treated as being a bad block, and a control unit configured to transmit the program data to the memory block, temporarily store the program data outputted from the page buffer unit, and transmit the stored program data to another page buffer unit coupled to another memory block.

### CROSS-REFERENCE TO RELATED APPLICATIONS

Priority to Korean patent application number 10-2009-0047819 filed on May 29, 2009, the entire disclosure of which is incorporated by reference herein, is claimed.

### BACKGROUND OF THE INVENTION

Exemplary embodiments of the present invention relate to a nonvolatile memory device and a method of programming the same and, more particularly, to a nonvolatile memory device and a method of programming the same, wherein another memory block is programmed in response to a determination as a result of a program operation that a specific memory block is a bad block.

Recently, there is an increasing demand for nonvolatile memory devices which can be electrically programmed and erased and which do not require the refresh function of rewriting data at specific time intervals.

The nonvolatile memory device includes a memory cell array having memory cells arranged in a matrix form for storing data and page buffers each for writing data into specific memory cells of the memory cell array or for reading data stored in specific memory cells. The page buffer includes a pair of bit lines coupled to specific memory cells, a register configured to temporarily store data to be programmed into a specific memory cell or to temporarily store data read from a specific memory cell, a sense node configured to detect the voltage level of a specific bit line or a specific register, and a bit line selection unit configured to control whether to couple the specific bit line to the sensing node.

FIG. 1 is a flowchart illustrating a conventional method of programming a nonvolatile memory device.

Referring to FIG. 1, external user data to be programmed are inputted at step 11. The inputted program data are temporarily stored in a controller and then inputted to a selected N^{th} page buffer corresponding to an address selected by the controller at step 12. The program data are then programmed into a selected memory block by performing a program operation with the page buffer at step 13. A determination is then made as to whether the program operation is a success or a failure by performing a verification operation at step 14. In more detail, after performing the program operation, a determination is then made as to whether the program operation has been successful by verifying the state of a memory cell. The number of memory cells in which the program operation has been unsuccessful is counted and them compared with the number of error code correction (ECC) bits. If, as a result of the comparison, the number of memory cells in which the program operation has been unsuccessful is less than the number of ECC bits, then the program operation is determined to be a success and the program operation is then terminated at step 15. However, if, as a result of the comparison, the number of memory cells in which the program operation has been unsuccessful is equal to or greater than the number of ECC bits, then the selected memory block is treated as being a bad block and is not used at step 16.

If the program operation is a failure and the selected memory block is treated as being a bad block, another memory block is selected, and a program operation is performed again in order to program the user program data in the selected another memory block. Accordingly, the time that it takes to perform the program operation is increased.

### SUMMARY OF THE INVENTION

One or more embodiments of the present invention relate to a nonvolatile memory device and a method of programming the same, which perform a program operation without a user inputting new program data.

A nonvolatile memory device according to an embodiment of the present invention includes a memory block having a number of memory cells, a page buffer unit coupled to the memory block and configured to temporarily store program data, to transmit the program data to the memory block, to perform a program operation for the program data, and to output the stored program data in response to the memory block being treated as being a bad block, and a control unit configured to transmit the program data to the memory block, temporarily store the program data outputted from the page buffer unit, and transmit the stored program data to another page buffer unit coupled to another memory block.

The page buffer unit includes a cache latch configured to temporarily store the program data, a main latch configured to receive the program data stored in the cache latch and to transmit the received program data to the memory block in response to the program operation being performed, and a flag latch configured to receive the program data stored in the main latch and to output the received program data in response to the memory block being treated as being the bad block.

The page buffer unit further includes a bit line selection unit configured to couple a bit line of the memory block to a sense node of the page buffer unit, a precharge unit configured to precharge the sense node, and a sense unit configured to detect a voltage level of the sense node.

The control unit selects the memory block in which the program data will be stored and transmits the program data to the page buffer unit corresponding to the selected memory block.

A method of programming a nonvolatile memory device according to another embodiment of the present invention includes storing program data in a control unit, transmitting the program data to a page buffer unit coupled to a selected memory block and storing the program data in the page buffer unit, programming the program data into the selected memory block using the page buffer unit, checking a state of the program operation on the selected memory block, and, in response to the selected memory block being determined to be a bad block as a result of the check, reading the program data stored in the page buffer unit and storing the read program data in the control unit, and transmitting the program data, stored in the control unit, to a new page buffer unit coupled to a new memory block other than the selected memory block, and programming the program data into the new memory block.

Transmitting the program data to a page buffer unit coupled to a selected memory block and storing the program data in the page buffer unit includes storing the program data in a first latch of the page buffer unit, and transmitting the program data, stored in the first latch, to a second latch of the page buffer unit.

Programming the program data into the selected memory block using the page buffer unit includes transmitting the program data, stored in the first latch, to the selected memory block, and programming the program data by supplying a program voltage to the selected memory block.

Reading the program data stored in the page buffer unit and storing the read program data in the control unit includes reading the program data stored in the second latch and storing the read program data in the control unit.

### BRIEF DESCRIPTION OF THE DRAWINGS

FIG. 1 is a flowchart illustrating a conventional method of programming a nonvolatile memory device;

FIG. 2 is a block diagram of a nonvolatile memory device according to an embodiment of the present invention;

FIG. 3 is a detailed circuit diagram of a first page buffer unit shown in FIG. 2;

FIG. 4 is a flowchart illustrating an operation of programming the nonvolatile memory device according to an embodiment of and the present invention.

### DESCRIPTION OF EMBODIMENTS

Hereinafter, embodiments of the present invention are described in detail with reference to the accompanying drawings. The drawing figures are provided to allow those having ordinary skill in the art to understand the scope of the embodiments of the present invention.

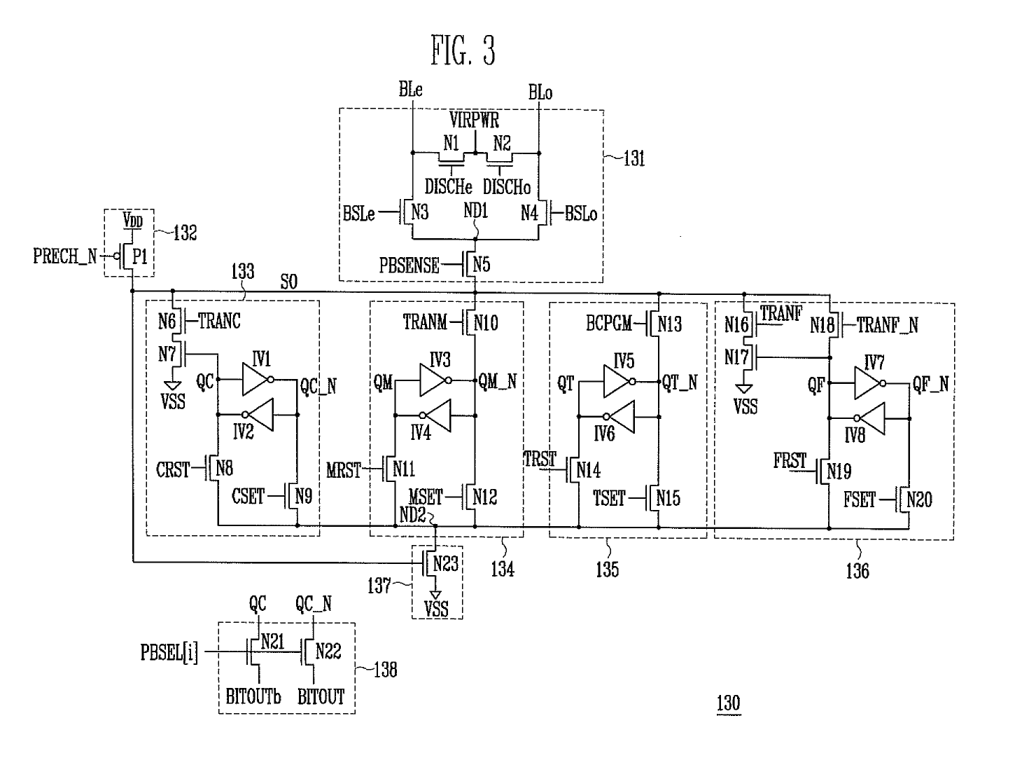

FIG. 2 is a block diagram of a nonvolatile memory device according to an embodiment of this disclosure.

Referring to FIG. 2, the nonvolatile memory device includes a number of memory blocks (i.e., first and second memory blocks 110 and 120), a number of first and second page buffer units 130 and 140, and a control unit 150.

Each of the first and second memory blocks 110 and 120 includes a number of memory cells configured to store program data. The first and second page buffer units 130 and 140 are respectively coupled to the first and second memory blocks 110 and 120 and are configured to respectively transfer program data, received from the control unit 150, to the first and second memory blocks 110 and 120, in order to program the program data. The control unit 150 is configured to transmit external program data to a selected first page buffer unit 130. If a program operation performed on the first memory block 110 coupled to the selected first page buffer unit 130 is determined to be failure and the first memory block 110 is treated as being a bad block, then the control unit 150 reads the external program data stored in the first page buffer unit 130 and transfers the external program data to a next selected second page buffer unit 140.

FIG. 3 is a detailed circuit diagram of the first page buffer unit 130 shown in FIG. 2. The first and second page buffer units 130 and 140 have the same construction, and so only the first page buffer unit 130 is described as an example.

The page buffer unit 130 includes a bit line selection unit 131, a precharge unit 132, a cache latch 133, a main latch 134, a temporary latch 135, a flag latch 136, a sense unit 137, and a data read unit 138.

The bit line selection unit 131 includes a number of NMOS transistors N1 to N5. The NMOS transistor N1 and the NMOS transistor N2 are coupled in series between an even bit line BLe and an odd bit line BLo coupled to the first memory block 110 and are configured to supply the bit lines BLe and BLo with a bias voltage VIRPWR in response to respective discharge signals DISCHe and DISCHo. The NMOS transistors N3 and N4 are coupled between the bit lines BLe and BLo and a common node ND1 and are configured to couple the common node ND1 to the bit lines BLe and BLo in response to respective bit line selection signals BSLe and BSLo. The NMOS transistor N5 is coupled between the common node ND1 and a sense node SO and is configured to couple the command node ND1 to the sense node SO in response to a sense signal PBSENSE.

The precharge unit 132 includes a PMOS transistor P1 coupled between a voltage terminal V_{DD} and the sense node SO. The PMOS transistor P1 is configured to supply the power source voltage V_{DD} to the sense node SO or block the supply of the power source voltage V_{DD} to the sense node SO in response to a precharge signal PRECH_N.

The cache latch 133 includes a number of NMOS transistors N6 to N9 and inverters IV1 and IV2.

The inverters IV1 and IV2 are cross-coupled in parallel between a first node QC and a second node QC_N to form a latch structure. The NMOS transistor N6 and the NMOS transistor N7 are coupled in series between the sense node SO and a ground power source voltage VSS. The NMOS transistor N16 is turned on in response to a transfer signal TRANC. The NMOS transistor N7 is turned on in response to the voltage level of the first node QC, to change the voltage level of the sense node SO according to the value of data stored in the latch. The NMOS transistor N8 and the NMOS transistor N9 are coupled between a reset node ND2, and the first node QC and the second node QC_N. The NMOS transistor N8 is configured to couple the first node QC to the reset node ND2 in response to a first cache control signal CRST. The NMOS transistor N9 is configured to couple the second node QC_N to the reset node ND2 in response to a second cache control signal CSET.

The main latch 134 includes a number of NMOS transistors N10 to N12 and inverters IV3 and IV4.

The inverters IV3 and IV4 are cross-coupled in parallel between a third node QM and a fourth node QM_N to form a latch structure. The NMOS transistor N10 is coupled between the sense node SO and the fourth node QM_N. The NMOS transistor N10 is configured to change the voltage level of the sense node SO according to the value of data stored in the latch in response to a transfer signal TRANM. The NMOS transistor N11 and the NMOS transistor N12 are coupled between the reset node ND2, and the third node QM and the fourth node QM_N. The NMOS transistor N11 is configured to couple the third node QM to the reset node ND2 in response to a first main control signal MRST. The NMOS transistor N12 is configured to couple the fourth node QM_N to the reset node ND2 in response to a second main control signal MSET.

The temporary latch 135 includes a number of NMOS transistors N13 to N15 and inverters IV5 and IV6.

The inverters IV5 and IV6 are cross-coupled in parallel between a fifth node QT and a sixth node QT_N to form a latch structure. The NMOS transistor N13 is coupled between the sense node SO and the sixth node QT_N and is configured to change the voltage level of the sense node SO according to the value of data stored. The NMOS transistor N14 and the NMOS transistor N15 are coupled between the reset node ND2, and the fifth node QT and the sixth node QT_N. The NMOS transistor N14 is configured to couple the fifth node QT to the reset node ND2 in response to a first temporary control signal TRST. The NMOS transistor N15 is configured to couple the sixth node QT_N to the reset node ND2 in response to a second temporary control signal TSET.

The flag latch 136 includes a number of NMOS transistors N16 to N20 and inverters IV7 and IV8.

The inverters IV7 and IV8 are cross-coupled in parallel between a seventh node QF and an eighth node QF_N to form a latch structure. The NMOS transistor N16 and the NMOS transistor N17 is coupled in series between the sense node SO and the ground power source voltage VSS, and the NMOS transistor N16 is turned on in response to a transfer signal TRANF. The NMOS transistor N17 is turned on in response to the voltage level of the seventh node QF, to change the voltage level of the sense node SO according to the value of data stored in the latch. The NMOS transistor N18 is coupled between the sense node SO and the seventh node QF and is configured to change the voltage level of the sense node SO according to the value of data stored in the latch in response to a transfer signal TRANF_N. The NMOS transistor N19 and the NMOS transistor N20 are coupled between the reset node ND2, and the seventh node QF and the eighth node QF_N. The NMOS transistor N19 is configured to couple the seventh node QF to the reset node ND2 in response to a first flag control signal FRST. The NMOS transistor N20 is configured to couple the eighth node QF_N to the reset node ND2 in response to a second flag control signal FSET.

The sense unit 137 includes an NMOS transistor N23. The NMOS transistor N23 is coupled between the reset node ND2 and the ground power source voltage VSS and is turned on in response to the voltage level of the sense node SO, to supply the reset node ND2 with the ground power.

The data read unit 138 includes NMOS transistors N21 and N22. The NMOS transistors N21 and N22 are respectively coupled to the first node QC and the second node QC_N of the cache latch 133. The NMOS transistors N21 and N22 are configured to output the voltage levels of the first node QC and the second node QC_N as respective first and second output signals BITOUTb and BITOUT in response to a page buffer selection signal PBSEL[i].

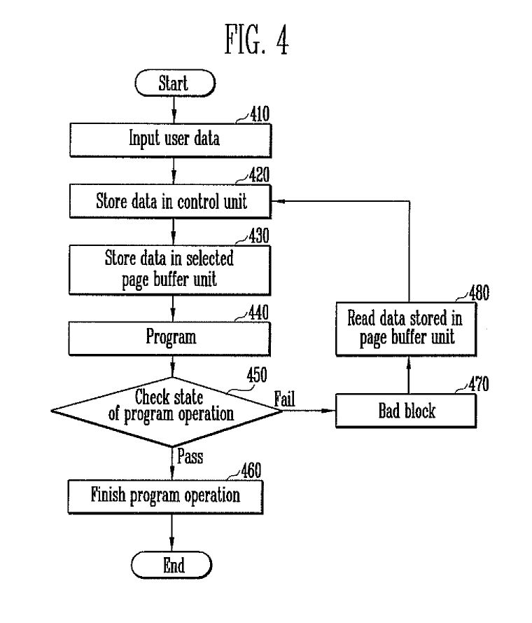

FIG. 4 is a flowchart illustrating an operation of programming the nonvolatile memory device according to an embodiment of the present invention.

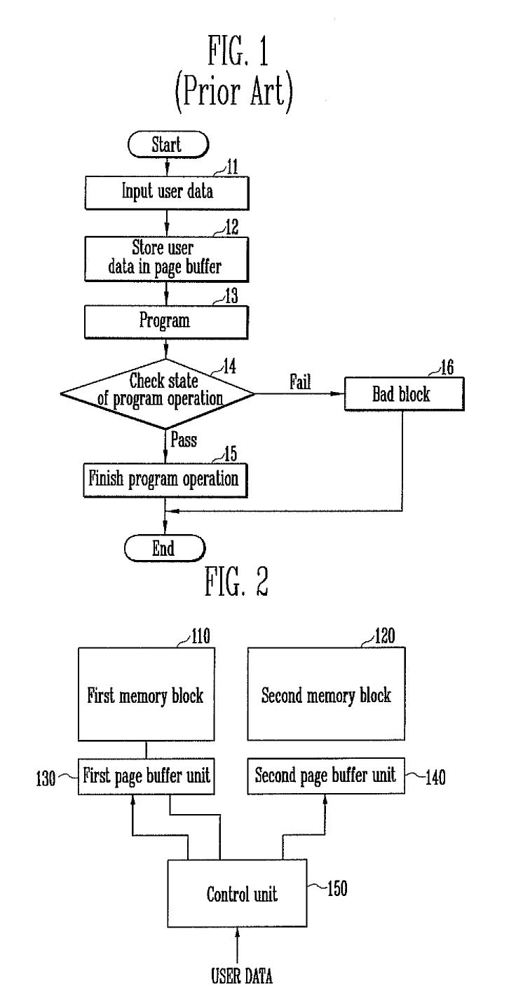

The operation of programming the nonvolatile memory device according to an embodiment of the present invention is described below with reference to FIGS. 1 to 4.

External data to be programmed are inputted at step 410. The inputted program data are then temporarily stored in the control unit 150 at step 420. The control unit 150 selects a memory block (e.g., the first memory block 110) in which the program data will be stored and stores the program data in the first page buffer unit 130 corresponding to the first memory block 110 at step 430.

The process of storing the program data in the first page buffer unit 130 is described in more detail below.

First, the precharge unit 132 of the first page buffer unit 130 supplies the sense node SO with the power source voltage V_{DD} in response to the precharge signal PRECH_N of a low level. In response thereto, the sense unit 137 supplies the reset node ND2 with the ground power source voltage VSS.

The first cache control signal CRST is then supplied to the cache latch 133, the first main control signal MRST is supplied to the main latch 134, the first temporary control signal TRST is supplied to the temporary latch 135, and the first flag control signal FRST is supplied to the flag latch 136, to respectively reset the first node QC, the third node QM, the fifth node QT, and the seventh node QF to a low level.

The second cache control signal CSET of either a high level or a low level, depending on a state of the program data, is then supplied to the cache latch 133, to either maintain or change the voltage levels of the first node QC and the second node QC_N. For example, when the value of the program data is “0”, the second cache control signal CSET of a high level is supplied to reset the first node QC to a high level and the second node QC_N to a low level.

The precharge unit 132 then supplies the power source voltage V_{DD} to the sense node SO in response to the precharge signal PRECH_N of a low level, to precharge the sense node SO to a high level.

In response to the transfer signal TRANC of a high level, the voltage level of the sense node SO is then either maintained at a high level or discharged to a low level according to a value of the program data stored in the cache latch 133. For example, when the value of the program data is “0”, the voltage level of the sense node SO is discharged to a low level.

The transfer signal TRANSM is then supplied to the main latch 134, and the program signal BCPGM is supplied to the temporary latch 135. The program data are stored in the main latch 134 and the temporary latch 135 according to the voltage level of the sense node SO. For example, when the value of the program data is “0”, the third node QM of the main latch 134 is reset to a high level, and the seventh node QF of the temporary latch 135 is reset to a low level.

The program data are then stored in the flag latch 136 in the same manner as the program data stored in the cache latch 133 being stored in the main latch 134 and the temporary latch 135.

A program operation is then performed on a selected memory cell of the first memory block 110 at step 440. In other words, the program data stored in the main latch 134 are transmitted to the bit line BLe or BLo coupled to the selected memory cell through the bit line selection unit 131. A program voltage Vpgm is then supplied to a word line coupled to the memory cell to program the program data in the memory cell.

A verification operation is then performed on the program operation to check the state of the first memory block 110 at step 450. The verification operation is performed by reading the data programmed into the memory cell using a verification voltage and comparing the read data and the program data.

The verification operation is determined to be a pass in response to the number of program fail bits in the first memory block being less than the number of ECC bits as a result of the check, and the program operation is terminated at step 460.

However, the first memory block 110 is treated as being a bad block and is not used at step 470 in response to the number of program fail bits in the first memory block being equal to or greater than the number of ECC as a result of the check.

The program data stored in the first page buffer unit 130 are then read and stored in the control unit 150 at step 480.

In this case, data stored in the flag latch 136, of the program data stored in the page buffer unit 130, are read.

Subsequently, the program data stored in the control unit 150 are transmitted to a new page buffer unit (e.g., the second page buffer unit 140) corresponding to a new memory block (e.g., the second memory block 120) which has been selected by the control unit 150. The above program operation is performed again.

As described above, according to an embodiment of the present invention, if a selected memory block is treated as being a bad block as a result of checking a program operation, then the control unit reads program data, stored in a selected page buffer when a program operation is performed, without receiving external data again, and transmits the read program data to a new page buffer corresponding to a newly selected memory block. The program data are programmed into a memory cell corresponding to the new page buffer. Accordingly, the time that it takes to perform the program operation is reduced.

What is claimed is:

1. A nonvolatile memory device, comprising:
a memory block having a number of memory cells;
a page buffer unit coupled to the memory block and configured to temporarily store program data, to transmit the program data to the memory block, to perform a program operation for the program data, and to output the stored program data if the memory block is treated as being a bad block; and
a control unit configured to transmit the program data to the memory block, temporarily store the program data outputted from the page buffer unit, and to transmit the stored program data to another page buffer unit coupled to another memory block.

2. The nonvolatile memory device of claim 1, wherein the page buffer unit comprises:
a cache latch configured to temporarily store the program data;
a main latch configured to receive the program data stored in the cache latch and to transmit the received program data to the memory block in response to the program operation being performed; and
a flag latch configured to receive the program data stored in the main latch and to output the received program data in response to the memory block being treated as being the bad block.

3. The nonvolatile memory device of claim 2, wherein the page buffer unit further comprises:
a bit line selection unit configured to couple a bit line of the memory block to a sense node of the page buffer unit;
a precharge unit configured to precharge the sense node; and
a sense unit configured to detect a voltage level of the sense node.

4. The nonvolatile memory device of claim 1, wherein the control unit selects the memory block in which the program data will be stored and transmits the program data to the page buffer unit corresponding to the selected memory block.

5. A method of programming a nonvolatile memory device, the method comprising:
storing program data in a control unit;
transmitting the program data to a page buffer unit coupled to a selected memory block and storing the program data in the page buffer unit;
programming the program data into the selected memory block with the page buffer unit;
checking a state of the program operation on the selected memory block;
reading the program data stored in the page buffer unit and storing the read program data in the control unit in response to the selected memory block being determined to be a bad block as a result of the check; and
transmitting the program data, stored in the control unit, to a new page buffer unit coupled to a new memory block other than the selected memory block and programming the program data into the new memory block.

6. The method of claim 5, wherein transmitting the program data to a page buffer unit coupled to a selected memory block and storing the program data in the page buffer unit comprises:
storing the program data in a first latch of the page buffer unit; and
transmitting the program data, stored in the first latch, to a second latch of the page buffer unit.

7. The method of claim 6, wherein programming the program data into the selected memory block with the page buffer unit comprises:
transmitting the program data, stored in the first latch, to the selected memory block; and
programming the program data by supplying a program voltage to the selected memory block.

8. The method of claim 6, wherein reading the program data stored in the page buffer unit and storing the read program data in the control unit comprises reading the program data stored in the second latch and storing the read program data in the control unit.

9. A method of programming a nonvolatile memory device, the method comprising:
storing program data in a control unit;
transmitting the program data to a first page buffer unit coupled to a first memory block and storing the program data in the first page buffer unit;
programming the program data into the first memory block with the first page buffer unit;
checking a state of the program operation on the first memory block;
terminating the program operation in response to a number of program fail bits being less than a number of error correction code (ECC) bits as a result of the check;
treating the first memory block as a bad block in response to the number of program fail bits being equal to or greater than the number of ECC bits as a result of the check;
reading the program data, stored in the first page buffer treated as being the bad block, and storing the read program data in the control unit; and
transmitting the program data stored in the control unit to a second page buffer coupled to a second memory block, and programming the program data into the second memory block.

10. The method of claim 9, wherein transmitting the program data to a first page buffer unit coupled to a first memory block and storing the program data in the first page buffer unit comprises:
storing the program data in a first latch of the first page buffer; and
transmitting the program data, stored in the first latch, to a second latch of the first page buffer and storing the program data in the second latch.

11. The method of claim 10, wherein reading the program data, stored in the first page buffer being treated as being the bad block, and storing the read program data in the control unit comprises reading the program data stored in the second latch and storing the read program data in the control unit.
